(19) United States
(12) Patent Application Publication
(10) Pub. No.: US 2008/0121274 A1
(43) Pub. Date: May 29, 2008

(54) SOLAR CELL MODULE

(75) Inventor: Toshio YAGIURA, Kobe (JP)

Correspondence Address: MOTS LAW, PLLC, 1001 PENNSYLVANIA AVE. N.W., SOUTH, SUITE 600, WASHINGTON, DC, 20004, US

(73) Assignee: SANYO ELECTRIC CO., LTD., Moriguchi (JP)

(21) Appl. No.: 11/945,315

(22) Filed: Nov. 27, 2007

(30) Foreign Application Priority Data
Nov. 28, 2006 (JP) JP2006-320144

(51) Int. Cl. H01L 31/04

(52) U.S. Cl. 136/252

(57) ABSTRACT

In a solar cell module 10, a first removed portion 23 and a second removed portion 24, which penetrate a photoelectric conversion layer 13, are provided along a first groove portion 17. A back surface electrode 14 is filled into the first removed portion 23 and the second removed portion 24.

### CROSS REFERENCE TO RELATED APPLICATION

This application is based upon and claims the benefit of priority from the prior Japanese Patent Application No. P 2006-320144, filed on Nov. 28, 2006; the entire contents of which are incorporated herein by reference.

### BACKGROUND OF THE INVENTION

1. Field of the Invention

The present invention relates to a solar cell module in which a plurality of photovoltaic elements is arranged.

2. Description of the Related Art

In recent years, in order to make cost reduction and efficiency enhancement of a solar cell compatible with each other, development of a thin-film solar cell module in which usage of raw materials is small has been energetically performed. An example of a cross-sectional view of the thin-film solar cell module as described above is shown in FIG. 1.

As shown in FIG. 1, a thin-film solar cell module 10 includes: a first electrode 12 stacked on a transparent substrate 11 of glass or the like; a photoelectric conversion layer 13 stacked on the first electrode 12; and second electrode 14 stacked on the photoelectric conversion layer 13. Moreover, the thin-film solar module 10 is completed by adhering a protective member 16 of polyethylene terephthalate (PET) or the like by a sealing material 15 of ethylene vinyl acetate (EVA) or the like (for example, refer to Japanese Patent Laid-Open Publication No. 2003-17722).

Note that, though the sealing material 16 can prevent invasion of moisture from the outside to some extent, the sealing material 16 cannot prevent the invasion of the moisture completely.

In general, the thin-film solar cell module 10 is used outdoors for a long period of time, and accordingly, it is necessary that the thin-film solar cell module 10 be provided with sufficient moisture resistance for maintaining a stable and high power generation capability even if the moisture permeate through the sealing material 16.

However, as shown in FIG. 1, the conventional thin-film solar cell module 10 includes a first groove portion 17 that electrically separates a power generation region 21 having a plurality of photovoltaic elements 20 and a non-power generation region 22 arranged along the periphery of the power generation region 21. Each of the plurality of photovoltaic elements 20 is formed by sequentially stacking a transparent conductive film 12, a photoelectric conversion layer 13, and a back surface electrode 14. The moisture that has invaded the first groove portion 17 through the protective member 16 and the sealing material 15 reaches an interface between the transparent substrate 11 and the photoelectric conversion layer 13. The moisture that reached the interface peels the photoelectric conversion layer 13 of which adhesion force with the transparent substrate 11 is relatively weak.

There has been a problem that an output decrease and a defective appearance of the thin film solar cell module 10 occur owing to that the photoelectric conversion layer 13 is peeled from the transparent substrate 11 as described above.

### BRIEF SUMMARY OF THE INVENTION

In consideration for the above-described problem, it is an object of the present invention to provide a thin-film solar cell module capable of preventing a progress of the peeling of the photoelectric conversion layer even if the peeling occurs owing to the invasion of the moisture.

A first aspect of the present invention is the provision of a solar cell module in which a plurality of photovoltaic elements is arranged, comprising a transparent substrate, and a first electrode stacked on the transparent substrate, and a photoelectric conversion layer stacked on the first electrode; a second electrode stacked on the photoelectric conversion layer, and a protective member adhered above the second electrode by a sealing material, a first removed portion provided in the photoelectric conversion layer, wherein each of the plurality of photovoltaic elements has a oblong shape that is extended in a longitudinal direction, and is arranged along a direction perpendicular to the longitudinal direction, and a power generation region that includes the plurality of photovoltaic elements is electrically separated from a non-power generation region that is provided along a periphery of the power generation region by a first groove portion, and the first removed portion penetrates the photoelectric conversion layer from the second electrode side to the transparent substrate side, and the first removed portion is provided along the first groove portion in the power generation region, and the second electrode is filled into the first removed portion.

A second aspect of the present invention is related to the first aspect of the present invention, and is summarized in that the solar cell has a second groove portion which separates the photoelectric conversion layer and the second electrode for each of the plurality of photovoltaic elements, wherein the first removed portion provided along the direction perpendicular to the longitudinal direction is formed on the transparent substrate, and is electrically separated by the second groove portions.

A third aspect of the present invention is related to the first aspect of the present invention, and is summarized in that the first removed portion provided along the longitudinal direction is formed on the transparent substrate or on the first electrode.

A fourth aspect of the present invention is related to the first aspect of the present invention, and is summarized in that the solar cell has a second removed portion provided in the photoelectric conversion layer, wherein the second removed portion penetrates the photoelectric conversion layer from the second electrode side to the transparent substrate side, the second removed portion is provided along the first groove portion in the non-power generation region, and the second electrode is filled into the second removed portion.

### BRIEF DESCRIPTION OF THE SEVERAL VIEWS OF THE DRAWINGS

FIG. 1 is a cross-sectional view showing a configuration of a conventional solar cell module.

FIG. 2 is a top view of a solar cell module according to an embodiment.

FIG. 3 is a cross-sectional view of a solar cell module according to Embodiment 1, taken along a direction perpendicular to a longitudinal direction of FIG. 2.

FIGS. 4A and 4B are cross-sectional views of the solar cell module according to Embodiment 1, taken along the longitudinal direction of FIG. 2.

FIGS. 5A and 5B are views showing a manufacturing method of the solar cell module according to this embodiment (No. 1).

FIGS. 6A and 6B are views showing the manufacturing method of the solar cell module according to this embodiment (No. 2).

FIG. 7 is a cross-sectional view of a solar cell module according to Embodiment 2, taken along the direction perpendicular to the longitudinal direction of FIG. 2.

FIG. 8 is a cross-sectional view of a solar cell module according to Embodiment 3, taken along the longitudinal direction of FIG. 2.

FIG. 9 is a cross-sectional view of the conventional solar cell module, taken along the direction perpendicular to a longitudinal direction.

### DETAILED DESCRIPTION OF THE INVENTION

### First Embodiment

Next, a description will be made of a first embodiment of the present invention by using the drawings. In the following description of the drawings, the same or similar reference numerals are assigned to the same or similar portions. It should be noted that the drawings are schematic, and that ratios of the respective dimensions, and the like are different from actual ones. Hence, specific dimensions and the like should be determined in consideration for the following description. Moreover, it is a matter of course that portions in which mutual dimensional relationships and ratios are different among the drawings are incorporated therein.

### <Configuration of Solar Cell Module 10>

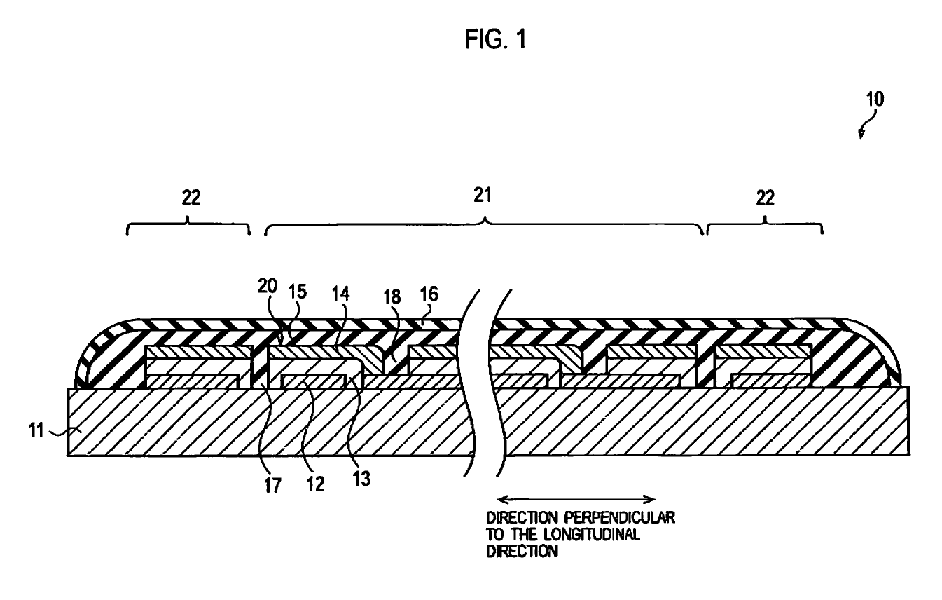

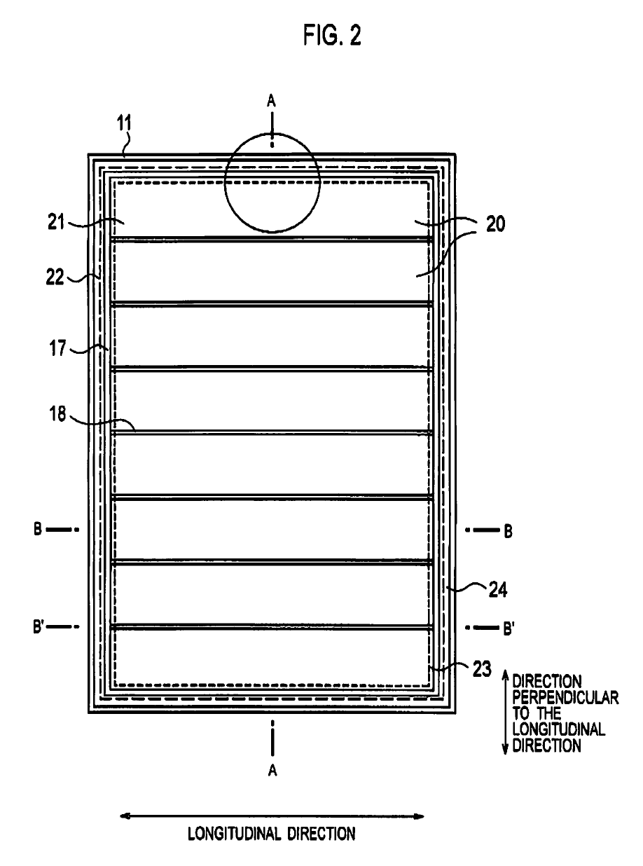

FIG. 2 shows a top view of a solar cell module 10 according to this embodiment. Note that a description will be made below while referring to FIG. 1 as appropriate.

On a transparent substrate 11, the solar cell module 10 includes: a power generation region 21 having a plurality of photovoltaic elements 20; a non-power generation region 22 arranged along the periphery of the power generation region 21.

Each of the plurality of photovoltaic elements 20 is formed by sequentially stacking a transparent conductive film 12, a photoelectric conversion layer 13, and a back surface electrode 14. The transparent conductive film 12 of one of the photovoltaic element 20 is connected to the back surface electrode 14 of the other photovoltaic element 20 adjacent to the one of the photovoltaic element 20, whereby the plurality of photovoltaic elements 20 are electrically connected in series. The photovoltaic elements 20 have a oblong shape extended in a longitudinal direction and a direction perpendicular to the longitudinal direction.

Here, in this specification, the term “longitudinal direction” stands for a direction approximately perpendicular to the direction where the solar cell module 10 is electrically connected in series. Moreover, in this specification, the term “direction perpendicular to the longitudinal direction” stands for a direction where the solar cell module 10 is electrically connected in series.

In addition, as shown in FIG. 1, the plurality of the photovoltaic elements 20 is protected from the outside air by a protective member 16 adhered above the back surface electrode 14 by a sealing material 15.

The power generation region 21 is formed by arranging he plurality of photovoltaic elements 20 along the direction perpendicular to the longitudinal direction.

The non-power generation region 22 is arranged along the periphery of the power generation region 21. The non-power generation region 22 is a ineffective region that do not contribute for generating electricity. The non-power generation region 22 is a stacked body formed by sequentially stacking the transparent conductive film 12, the photoelectric conversion layer 13 and the back surface electrode 14 in a similar way to the photovoltaic elements 20.

As shown in FIG. 1, a first groove portion 17 is a groove formed by removing the transparent conductive film 12, the photoelectric conversion layer 13 and the back surface electrode 14. Specifically, the first groove portion 17 electrically separates the power generation region 21 and the non-power generation region 22.

As shown in FIG. 1, a second groove portion 18 is a groove formed by removing the photoelectric conversion layer 13 and the back surface electrode 14. Specifically, the second groove portion 18 is a region where the transparent conductive film 12 of one of the photovoltaic element 20 is connected to the back surface electrode 14 of the other photovoltaic element 20 adjacent thereto. Each of the photovoltaic elements 20 is electrically connected in series by the back surface electrodes 14 formed partially in the second groove portions 18.

A first removed portion 23 penetrates the photoelectric conversion layer 13 from the back surface electrode 14 to the transparent substrate 11 in the power generation region 21. The first removed portion 23 is provided along the first groove portion 17. The back surface electrode 14 is filled into the first removed portion 23. Specifically, since the first removed portion 23 is provided in an inside of the power generation region 21, the first removed portion 23 is not visually recognized in the top view of the solar cell module 10. Hence, in FIG. 2, the first removed portion 23 is shown by a dotted line.

A second removed portion 24 penetrates the photoelectric conversion layer 13 from the back surface electrode 14 to the transparent conductive film 12 in the non-power generation region 22. The second removed portion 24 is provided along the first groove portion 17. The back surface electrode 14 is filled into the second removed portion 24. Specifically, since the second removed portion 24 is provided in an inside of the non-power generation region 22, the second removed portion 24 is not visually recognized in the top view of the solar cell module 10. Hence, in FIG. 2, the second removed portion 24 is shown by a dotted line.

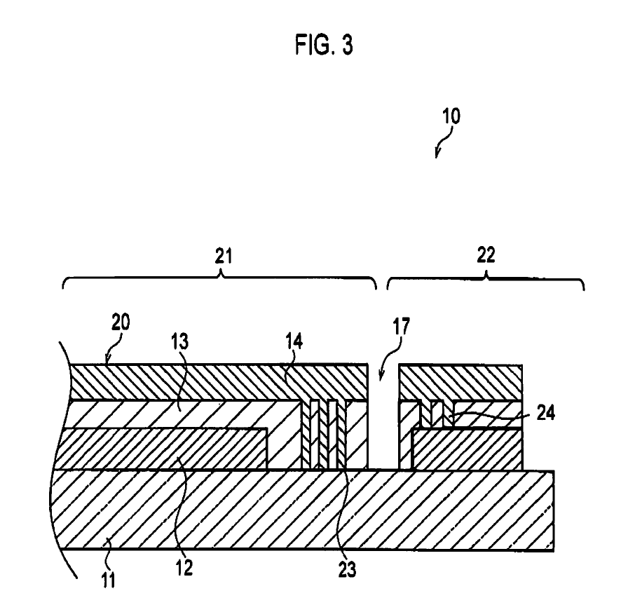

FIG. 3 is a cross-sectional view along a line A-A of FIG. 2, enlarging an upper portion (a circled portion) of FIG. 2.

As shown in FIG. 3, the solar cell module 10 according to this embodiment includes: the transparent substrate 11; the transparent conductive film 12 (first electrode) stacked on the transparent substrate 11; the photoelectric conversion layer 13 stacked on the transparent conductive film 12; and the back surface electrode 14 (second electrode) stacked on the photoelectric conversion layer 13. Note that, a description for the sealing material 15 and the protective member 16 will be omitted in this embodiment.

The transparent substrate 11 is a single substrate of the solar cell module 10. The transparent substrate 11 is composed of a member, such as glass, that has translucency and imperviousness.

The transparent conductive film 12 is formed in the rectangle shape in a plan view of the transparent substrate 11. The transparent conductive film 12 is composed of one or plural types of stacked bodies selected from a group of metal oxides in which Sn, Sb, F and Al are doped into ZnO, In₂O₃, SnO₂, CdO, TiO₂, CdIn₂O₄, Cd₂SnO₄ and Zn₂SnO₄. Note that ZnO is suitable as a material of the transparent conductive film since ZnO has high optical transparency, low resistance, and plasticity, and is inexpensive.

The photoelectric conversion layer 13 is formed in the rectangle shape on the transparent conductive film 12. The photoelectric conversion layer 13 according to this embodiment is formed by stacking a microcrystalline silicon semiconductor on an amorphous silicon semiconductor. Note that, in this specification, the term “microcrystalline” stands for one containing a large number of microcrystal grains, and also stands for a state partially including an amorphous state.

Here, the photoelectric conversion layer 13 is formed by sequentially stacking a p-i-n type amorphous silicon semiconductor and then sequentially stacking a p-i-n type microcrystalline silicon semiconductor. Such a tandem-type solar cell module has a structure in which two types of semiconductors different in optical absorption wavelength are stacked on each other. The tandem-type solar cell module can effectively utilize a solar light spectrum.

Moreover, in the photoelectric conversion layer 13 in the power generation region 21, the first removed portion 23 that penetrates the photoelectric conversion layer 13 from the back surface electrode 14 to the transparent substrate 11 is provided. The first removed portion 23 is provided along the first groove portion 17 in the power generation region 21. The back surface electrode 14 is filled into the first removed portion 23.

Note that, though the solar cell module 10 includes three first removed portions 23, it is a matter of course that the number of the first removed portion 23 may be one, and further.

Furthermore, in the photoelectric conversion layer 13 in the non-power generation region 22, the second removed portion 24 that penetrates the photoelectric conversion layer 13 from the back surface electrode 14 to the transparent conductive film 12 is provided. The second removed portion 24 is provided along the first groove portion 17 in the non-power generation region 22. The back surface electrode 14 is filled into the second removed portion 24.

Note that, though the solar cell module 10 includes two first removed portions 24, it is a matter of course that the number of the second removed portion 24 may be one, and further.

The back surface electrode 14 is formed in the rectangle shape on the photoelectric conversion layer 13. The back surface electrode 14 is composed of a conductive member such as Ag. A part of the back surface electrode 14 is filled into the first removed portion 23. Hence, the back surface electrode 14 contacts the transparent substrate 11 through the first removed portion 23.

FIG, 4A is a cross-sectional view along a line B-B (along the longitudinal direction) of FIG. 2.

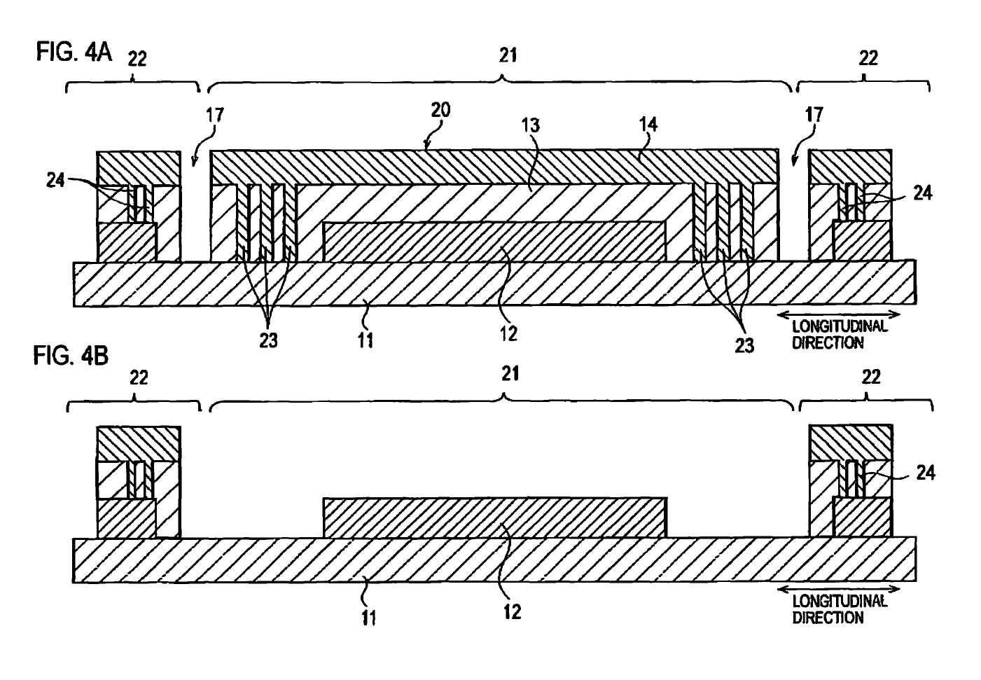

In the photoelectric conversion layer 13 in the power generation region 21, the first removed portion 23 that penetrates the photoelectric conversion layer 13 from the back surface electrode 14 to the transparent substrate 11 is provided along the first groove portion 17. The first removed portion 23 shown in FIG. 4A is a part provided along the direction perpendicular to the longitudinal direction.

In the photoelectric conversion layer 13 in the non-power generation region 22, the second removed portion 24 that penetrates the photoelectric conversion layer 13 from the back surface electrode 14 to the transparent substrate 11 is provided along the first groove portion 17. The second removed portion 24 shown in FIG. 4A is a part provided along the direction perpendicular to the longitudinal direction.

FIG. 4B is a cross-sectional view along a line B′-B′ (along the longitudinal direction along the second groove portion 18) of FIG. 2.

As shown in FIG. 4B, in the power generation region 21, the photoelectric conversion layer 13 and the back surface electrode 14, which are stacked on the transparent conductive film 12, are removed, whereby the second groove portion 18 is formed. Following such removal, the first removed portion 23 is also removed. Hence, the first removed portion 23 provided along the direction perpendicular to the longitudinal direction is partitioned at a predetermined interval by the second groove portion 18. Note that the predetermined interval mentioned here is an interval at which the photovoltaic elements 20 are arrayed along the direction perpendicular to the longitudinal direction.

### <Manufacturing Method of Solar Cell Module 10>

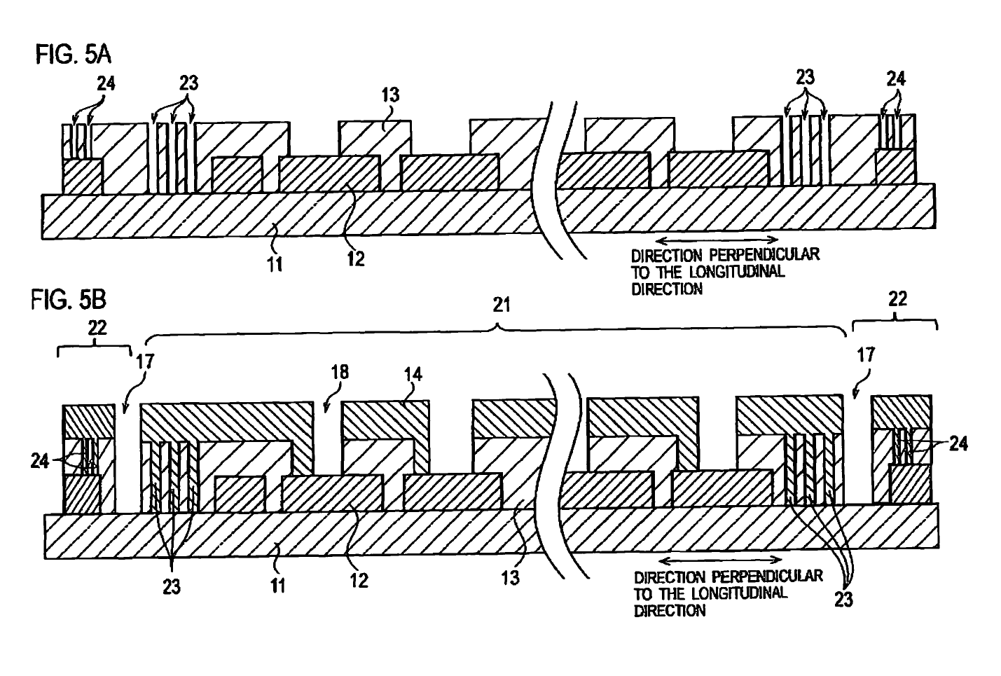

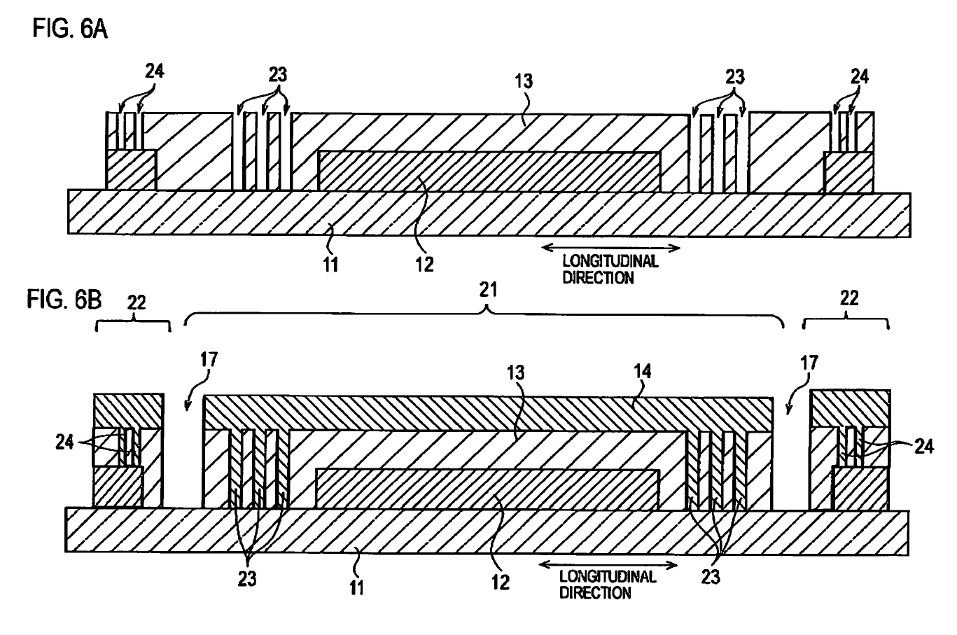

A description will be made of a manufacturing method of the solar cell module 10 according to this embodiment by using FIGS. 5A to 6B. FIGS. 5A and 5B are cross-sectional views along the line A-A of FIG. 2, and FIGS. 6A and 6B are cross-sectional views along the line B-B of FIG. 2.

The transparent conductive film 12 is formed on the transparent substrate 11 by sputtering method and the like. The transparent conductive film 12 is patterned in the rectangle shape by partially removing with a YAG laser from a back surface side opposite with a light incident side. Therefore, the transparent conductive film 12 is electrically separated for each of the photovoltaic elements 20. Moreover, the transparent conductive film 12 is reciprocatively partially removed with the YAG laser, being electrically separated into the power generation region 21 and the non-power generation region 22.

Next, the photoelectric conversion layer 13 is formed by a plasma chemical vapor deposition method. Specifically, on the transparent substrate 11, the p-i-n type amorphous silicon semiconductor is sequentially stacked, and then the p-i-n type microcrystalline silicon semiconductor is stacked, whereby the photoelectric conversion layer 13 is formed.

The photoelectric conversion layer 13 is patterned in the rectangle shape in such a manner that the YAG laser is irradiated from the back surface side onto positions separated at a predetermined interval from patterned positions of the transparent substrate 11. Therefore, the photoelectric conversion layer 13 is electrically separated for each of the photovoltaic elements 20.

Moreover, the photoelectric conversion layer 13 formed on the power generation region 21 is partially removed with the YAG laser from the back surface side. Therefore, the first removed portion 23 that penetrates the photoelectric conversion layer 13 on the transparent substrate 11 is formed. In this embodiment, three first removed portions 23 are formed, and accordingly, the photoelectric conversion layer 13 is partially removed with the YAG laser three times at a predetermined interval.

Furthermore, the photoelectric conversion layer 13 formed on the non-power generation region 22 is also partially removed with the YAG laser from the back surface side. Therefore, the second removed portion 24 that penetrates the photoelectric conversion layer 13 on the transparent conductive film 12 is formed. In this embodiment, two second removed portions 24 are formed, and accordingly, the photoelectric conversion layer 13 is partially removed with the YAG laser twice at a predetermined interval.

FIG. 5A and FIG. 6A show a state where the photoelectric conversion layer 13 is patterned, and the first removed portion 23 and the second removed portion 24 are formed.

Next, the back surface electrode 14 is formed on the photoelectric conversion layer 13 by the sputtering method and the like. The back surface electrode 14 is filled into the first removed portion 23, and into the second removed portion 24.

The back surface electrode 14 is patterned in the rectangle shape in such a manner that the YAG laser is irradiated from the light incident side onto positions separated at a predetermined interval from patterned positions of the photoelectric conversion layer 13. Therefore, the second groove portion 18 is formed, and the photovoltaic elements 20 are electrically connected in series.

Moreover, the YAG laser is irradiated from the light incident side so as to form the first groove portion 17 that electrically separates the power generation region 21 and the non-power generation region 22 from each other.

As described above, on the transparent substrate 11, the non-power generation region 22 is formed along the periphery of the power generation region 21, in which the plurality of photovoltaic element 20 is electrically connected in series.

FIG. 5B and FIG. 6B show a state where the first groove portion 17 is formed.

On the power generation region 21 and the non-power generation region 22, the sealing material 15 and the protective member 16 are sequentially arranged. With thermocompression in vacuo using a laminating apparatus, the sealing material 15 is cross-linked and stabilized.

As the sealing material 15, ethylene resin such as EEA, PVB, silicon, urethane, acryl, and epoxy resin may be used besides the EVA. Moreover, as the protective member 16, fluorine resins (ETFE, PVDF, PCTFE and the like), PC, a structure in which metal foil is sandwiched by glass and the like, SUS, and plate steel may be used.

In such a manner as described above, the solar cell module 10 according to this embodiment is formed. Note that a terminal box and extraction electrodes can be connected to the solar cell module 10, and an aluminum frame can be attached thereonto by butyl rubber and the like.

### <Function and Effect>

In the solar cell module 10 according to this embodiment, the first removed portion 23 and the second removed portion 24, which penetrate the photoelectric conversion layer 13, are provided along the first groove portion 17. The back surface electrode 14 is filled into the first removed portion 23 and the second removed portion 24.

Therefore, even if the moisture that has invaded the first groove portion 17 reaches the interface between the transparent substrate 11 and the photoelectric conversion layer 13, and the photoelectric conversion layer 13 is peeled from the transparent substrate 11, a progress of the peeling can be prevented by the first removed portion 23 and the second removed portion 24, which are filled with the back surface electrode 14. Because adhesiveness between the back surface electrode 14 and the transparent substrate 11 is strong. Accordingly, an output decrease and a defective appearance of the solar cell module 10 can be suppressed from occurring.

Specifically, the output decrease and the defective appearance in the power generation region 21 can be suppressed from occurring by the first removed portion 23, and further, a defective appearance in the non-power generation region 22 can be suppressed from occurring by the second removed portion 24.

### Second Embodiment

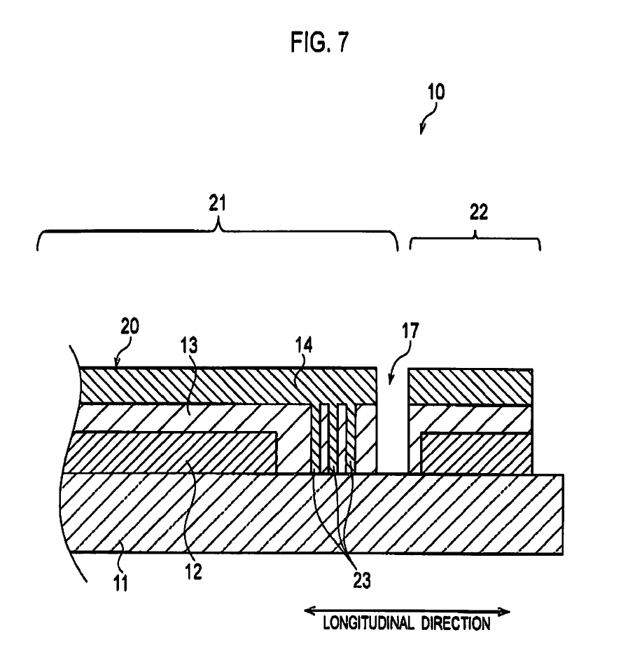

Next, a description will be made of a second embodiment of the present invention with reference to FIG. 7. Note that basic configuration and manufacturing method are similar to those of the first embodiment, and accordingly, different portions from those of the first embodiment will be described.

A solar cell module 10 according to this embodiment does not include the second removed portion 24 in the non-power generation region 22.

### <Configuration of Solar Cell Module 10>

A top view of the solar cell module 10 is similar to FIG. 2.

FIG. 7 is a cross-sectional view along the line A-A of FIG. 2, enlarging the upper portion (circled portion) of FIG. 2.

The solar cell module 10 includes only the first removed portion 23, and the second removed portion 24 is not provided in the non-power generation region 22.

Other configurations are similar to those of the first embodiment.

### <Manufacturing Method of Solar Cell Module 10>

In the manufacturing method according to this embodiment, the second removed portion 24 is not formed.

Specifically, in the first embodiment, the photoelectric conversion layer 13 is partially removed with the YAG laser from the back surface side, whereby the second removed portion 24 which penetrate the photoelectric conversion layer 13 on the transparent conductive film 12 is formed therein. Meanwhile, in this embodiment, such treatment is not performed.

Hence, in this embodiment, only the first removed portion 23 is formed, and the second removed portion 24 are not formed.

Other treatments are similar to those of the first embodiment.

### <Function and Effect>

In the solar cell module 10 according to this embodiment, the first removed portion 23 that penetrates the photoelectric conversion layer 13 is provided along the first groove portion 17. The back surface electrode 14 is filled into the first removed portion 23.

Therefore, even if the moisture that has invaded the first groove portion 17 reaches the interface between the transparent substrate 11 and the photoelectric conversion layer 13, and the photoelectric conversion layer 13 is peeled from the transparent substrate 11 in the power generation region 21, the progress of the peeling can be prevented by the first removed portion 23 filled with the back surface electrode 14. Because the adhesiveness between the back surface electrode 14 and the transparent substrate 11 is strong. Accordingly, the output decrease and the defective appearance of the solar cell module 10 can be suppressed from occurring.

Note that, though the defective appearance in the non-power generation region 22 cannot be suppressed from occurring, the output decrease that becomes a more serious trouble for the solar cell module 10 can be prevented. Moreover, the occurrence of the defective appearance in the power generation region 21 larger in area than the non-power generation region 22 can be suppressed.

### Third Embodiment

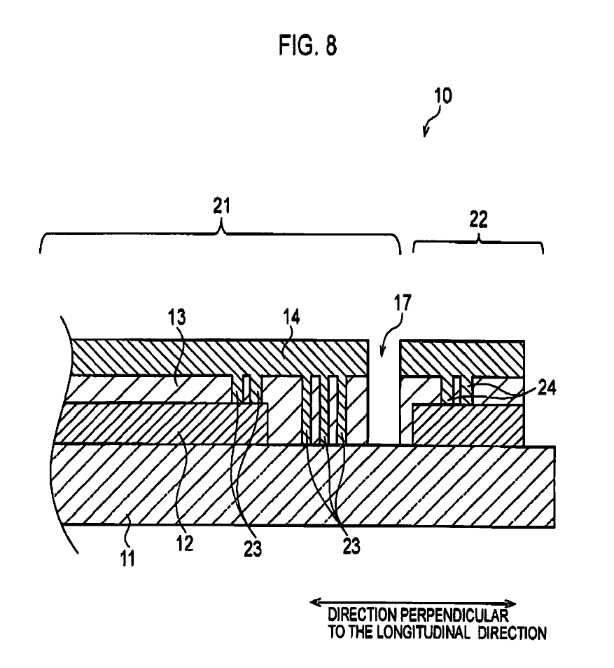

Next, a description will be made of a third embodiment of the present invention with reference to FIG. 8. Note that basic configuration and manufacturing method are similar to those of the first embodiment, and accordingly, different portions from those of the first embodiment will be described.

In a solar cell module 10 according to this embodiment, the first removed portion 23 that penetrates the photoelectric conversion layer 13 from the back surface electrode 14 to the transparent conductive film 12 is provided in the power generation region 21.

### <Configuration of Solar Cell Module 10>

A top view of the solar cell module 10 is similar to FIG. 2.

FIG. 8 is a cross-sectional view along the line A-A of FIG. 2, enlarging the upper portion (circled portion) of FIG. 2.

In the power generation region 21, the solar cell module 10 includes the first removed portion 23 that penetrates the photoelectric conversion layer 13 from the back surface 14 to the transparent conductive film 12, in addition to the first removed portion 23 that penetrates the photoelectric conversion layer 13 from the back surface electrode 14 to the transparent substrate 11.

Other configurations are similar to those of the first embodiment.

### <Manufacturing Method of Solar Cell Module 10>

In the manufacturing method according to this embodiment, in the photoelectric conversion layer 13 in the power generation region 21, the first removed portion 23 that penetrates the photoelectric conversion layer 13 from the back surface 14 to the transparent conductive film 12, are formed in addition to the first removed portion 23 which communicate from the back surface electrode 14 to the transparent substrate 11.

Specifically, in the first embodiment, the photoelectric conversion layer 13 formed in the power generation region 21 is partially removed with the YAG laser from the back surface side, whereby the first removed portion 23 which penetrates the photoelectric conversion layer 13 on the transparent substrate 11 are formed therein. Meanwhile, in this embodiment, the photoelectric conversion layer 13 is further partially removed with the YAG laser from the back surface side, whereby the first removed portion 23 which penetrates the photoelectric conversion layer 13 on the transparent conductive film 12 are formed.

In other words, in the power generation region 21, two types of the first removed portion 23 provided along the first groove portion 17 are formed.

Other treatments are similar to those of the first embodiment.

### <Function and Effect>

In the solar cell module 10 according to this embodiment, not only the first removed portion 23, which penetrates the photoelectric conversion layer 13 from the back surface electrode 14 to the transparent substrate 11, but also the first removed portion 23 which penetrates the photoelectric conversion layer 13 from the back surface electrode 14 to the transparent conductive film 12 are provided along the first groove portion 17. The back surface electrode 14 is filled into the first removed portion 23.

As described above, in accordance with the solar cell module 10 according to this embodiment, the first removed portion 23 which penetrates the photoelectric conversion layer 13 from the back surface electrode 14 to the transparent conductive film 12 is further provided, whereby the progress of the peeling of the photoelectric conversion layer 13 can be more fully prevented. Accordingly, the output decrease and the defective appearance can be more fully suppressed from occurring.

### Other Embodiments

Although the present invention has been described by the above-described embodiments, it should not be understood that the description and the drawings, which form a part of this disclosure, limits this invention. From this disclosure, a variety of alternative embodiments, examples and application technologies will become apparent for those skilled in the art.

For example, though the photoelectric conversion layer 13 in which the amorphous silicon semiconductor and the microcrystalline silicon semiconductor are sequentially stacked is used in the above-described embodiments, a similar effect can be obtained even in the case of using a single layer of the microcrystalline or amorphous silicon semiconductor or a stacked body of three or more layers thereof.

Moreover, though, in the above-described embodiment, the description has been made of the configuration in which the second removed portion 24 which penetrates the photoelectric conversion layer 13 from the back surface electrode 14 to the transparent conductive film 12 is provided in the non-power generation region 22, second removed portion 24 which penetrates the photoelectric conversion layer 13 from the back surface electrode 14 to the transparent substrate 11 may be further provided. In accordance with this, the progress of the peeling of the photoelectric conversion layer 13 in the non-power generation region 22 can be more fully prevented.

Furthermore, though, in the above-described embodiment, the description has been made of the configuration in which the second removed portion 24 which penetrates the photoelectric conversion layer 13 from the back surface electrode 14 to the transparent conductive film 12 are provided in the power generation region 21, the second removed portion 24 may penetrate the photoelectric conversion layer 13 from the back surface electrode 14 to the transparent substrate 11. Furthermore, these two types of the second removed portion 24 may be provided. In such a way, the progress of the peeling of the photoelectric conversion layer 13 from the transparent substrate 11 in the non-power generation region 22 can be more fully prevented.

As described above, it is a matter of course that the present invention incorporates the variety of embodiments that are not described herein. Hence, the technical scope of the present invention is to be defined only by the invention specifying items according to the scope of claims reasonable based on the above description.

### EXAMPLE

Although the solar cell module according to the present invention will be specifically described below while mentioning examples, the present invention is not limited to the examples to be described below. Accordingly, various changes may be made without departing from the scope of the invention.

### Example 1

As a solar cell module according to Example 1 of the present invention, the solar cell module 10 shown in FIG. 3 was fabricated in the following manner.

On the glass substrate 11 with a thickness of 4 mm, the ZnO electrode 12 with a thickness of 600 nm was formed by the sputtering method. Thereafter, the YAG laser was irradiated from the back surface side of the glass substrate 11, and the ZnO electrode 11 was patterned in the rectangle shape. For such a laser separation process, an Nd: YAG laser with a wavelength of approximately 1.06 μm, an energy density of 10W, and a pulse frequency of 3 kHz, was used. Here, at the boundary division between the power generation region 21 and the non-power generation region 22, a groove with a width of 3 mm was formed by multiple reciprocating removal with the YAG laser.

Next, by the plasma CVD method, the photoelectric conversion layer 13 formed of the amorphous silicon semiconductor layer and the microcrystalline silicon semiconductor layer was formed. Specifically, for the amorphous silicon semiconductor layer, by the plasma CVD method, a p-type amorphous silicon semiconductor layer with a film thickness of 10 nm was formed of mixed gas of SiH₄, CH₄, H₂ and B₂H₆, an i-type amorphous silicon semiconductor layer with a film thickness of 300 nm was formed of mixed gas of SiH₄ and H₂, an n-type amorphous silicon semiconductor layer with a film thickness of 20 nm was formed of mixed gas of SiH₄, H₂ and PH₃, and these layers were sequentially stacked on one another. Moreover, for the microcrystalline silicon semiconductor layer, by the plasma CVD method, a p-type microcrystalline silicon semiconductor layer with a film thickness of 10 nm was formed of mixed gas of SiH₄, H₂ and B₂H₆, an i-type microcrystalline silicon semiconductor layer with a film thickness of 2000 nm was formed of mixed gas of SiH₄ and H₂, an n-type microcrystalline silicon semiconductor layer with a film thickness of 20 nm was formed of mixed gas of SiH₄, H₂ and PH₃, and these layers were sequentially stacked on one another. Details of various conditions of the plasma CVD method are shown in Table 1.

TABLE 1
PLASMA CVD CONDITION

| | | SUBSTRATE | | REACTION | | FILM |
|---|---|---|---|---|---|---|
| | | TEMPERATURE | GAS FLOW | PRESSURE | RF POWER | PRESSURE |
| | LAYER | (° C.) | RATE (sccm) | (Pa) | (W) | (nm) |
| a-Si FILM | p- | 180 | SiH4: 300 | 106 | 10 | 10 |
| | LAYER | | CH4: 300 | | | |
| | | | H2: 2000 | | | |
| | | | B2H6: 3 | | | |
| | i- | 200 | SiH4: 300 | 106 | 20 | 300 |
| | LAYER | | H2: 2000 | | | |
| | n- | 180 | SiH4: 300 | 133 | 20 | 20 |
| | LAYER | | H2: 2000 | | | |
| | | | PH3: 5 | | | |
| MICROCRYSTALLINE | p- | 180 | SiH4: 10 | 106 | 10 | 10 |
| Si FILM | LAYER | | H2: 2000 | | | |
| | | | B2H6: 3 | | | |
| | i- | 200 | SiH4: 100 | 133 | 20 | 2000 |
| | LAYER | | H2: 2000 | | | |
| | n- | 200 | SiH4: 10 | 133 | 20 | 20 |
| | LAYER | | H2: 2000 | | | |
| | | | PH3: 5 | | | |

Moreover, the photoelectric conversion layer 13 was patterned in the rectangle shape by partially removing with the YAG laser from the light incident side onto positions apart by 50 μm from the patterned positions of the ZnO electrode 12.

Furthermore, the photoelectric conversion layer 13 formed in the power generation region 21 was partially removed with the YAG laser from the back surface side, whereby three first removed portions 23 with a width of 400 nm, which penetrate the photoelectric conversion layer 13 on the glass substrate 11, were formed.

Moreover, the photoelectric conversion layer 13 formed in the non-power generation region 22 was partially removed with the YAG laser from the light incident side, whereby two second removed portions 24 with a width of 400 nm, which penetrate the photoelectric conversion layer 13 on the ZnO electrode 12, were formed. For the laser separation process described above, an Nd: YAG laser with energy of 7W and a pulse frequency of 3 kHz was used.

Next, the Ag electrode 14 with a thickness of 200 nm was formed on the microcrystalline silicon semiconductor layer by the sputtering method. The Ag electrode 14 was filled into the first removed portion 23 and the second removed portion 24.

Next, the photoelectric conversion layer 13 and the Ag electrode 14 were patterned in the rectangle shape by partially removing with the YAG laser from the back surface side. In such a way, the second groove portions 18 were formed. For the laser separation process concerned, an Nd: YAG laser with energy of 7W and a pulse frequency of 4 kHz was used.

Next, the photoelectric conversion layer 13 and the Ag electrode 14 were partially removed by partially removing with the YAG laser from the light incident side, and the first groove portion 17 that electrically separates the power generation region 21 and the non-power generation region 22 from each other was formed. For the laser separation process, the Nd: YAG laser with energy of 7W and a pulse frequency of 4 kHz was used.

Next, the EVA 15 and the PET film 16 were sequentially arranged on the photovoltaic elements, and heat treatment was performed therefore at 150° C. for 30 minutes by using the laminating apparatus, whereby the EVA 15 was cross-linked, stabled.

Finally, the terminal box was attached, and the extraction electrodes were connected. In such a way, the solar cell module according to the example of the present invention was completed.

### Example 2

As a solar cell module according to Example 2 of the present invention, the solar cell module 10 shown in FIG. 7 was fabricated. In this example, similar processes to those of Example 1 were performed except that, in the non-power generation region 22, the second removed portion 24 with a width of 400 nm, which penetrate the photoelectric conversion layer 13 from the Ag electrode 14 to the ZnO electrode 12, were not formed.

Specifically, as shown in FIG. 7, the second removed portion 24 does not exist in the non-power generation region 22 of the solar cell module 10.

### Example 3

As a solar cell module according to Example 3 of the present invention, the solar cell module 10 shown in FIG. 8 was fabricated. In this example, similar processes to those of Example 1 were performed except that, in the power generation region 21, the first removed portion 23 with a width of 400 nm, which penetrate the photoelectric conversion layer 13 from the Ag electrode 14 to the ZnO electrode 12, were formed in addition to the first removed portion 23 with a width of 400 nm, which penetrate the photoelectric conversion layer 13 from the Ag electrode 14 to the glass substrate 11.

Specifically, as shown in FIG. 8, two types of the first removed portion 23 exist in the power generation region 21.

### CONVENTIONAL EXAMPLE

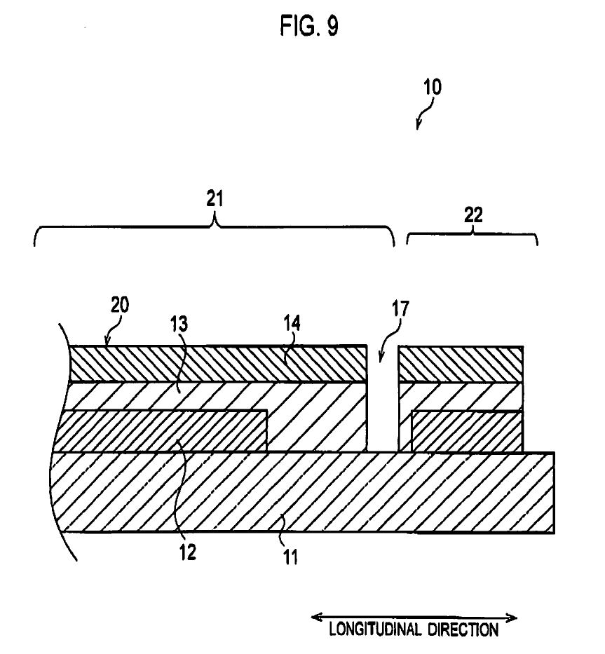

As a conventional example, a solar cell module 10 shown in FIG. 9 was fabricated. In the conventional example, the processes of forming the first removed portion 23 and the second removed portion 24 were not performed.

Specifically, as shown in FIG. 9, the first removed portion 23 and the second removed portion 24 do not exist in the power generation region 21 and the non-power generation region 22.

### <<Moisture Resistance Test>>

A moisture resistance test for comparing reliabilities between the solar cell modules according to Examples 1 to 3 and Conventional example was performed. Specifically, in conformity with IEC 61646, the respective modules were exposed for 1500 hours to an environment where a temperature was 85° C., and degree of humidity was 85%.

### <Results>

Results of the moisture resistance test are as follows.

TABLE 2
HUMIDITY RESISTANCE TEST RESULT

| | PEELING SITUATION | | | |
|---|---|---|---|---|
| | INITIAL | 500 HOURS | 1000 HOURS | 1500 HOURS |
| CONVENTIONAL | NOTHING WRONG | MICRO PEELING | PEELING | PEELING GREW |
| STRUCTURE | | OCCURRED IN A | PROGRESSED IN | IN POWER |
| | | PART OF POWER | POWER | GENERATION |
| | | GENERATION | GENERATION | REGION |
| | | REGION | REGION | |
| EXAMPLE 1 | NOTHING WRONG | NOTHING WRONG | NOTHING WRONG | NOTHING WRONG |
| EXAMPLE 2 | NOTHING WRONG | NOTHING WRONG | PEELING | PEELING |
| | | | OCCURRED IN | PROGRESSED |
| | | | NON-POWER | IN NON-POWER |
| | | | GENERATION | GENERATION |
| | | | REGION | REGION |
| EXAMPLE 3 | NOTHING WRONG | NOTHING WRONG | NOTHING WRONG | NOTHING WRONG |

As a result of visually observing the respective modules, in the conventional example, micro peeling occurred on the interface between the glass substrate 11 and the photoelectric conversion layer (amorphous silicon semiconductor layer) 13 within 500 hours. Thereafter, the peeling progressed with time. As a result of measuring the characteristics of the solar cell module 10 in which the peeling progressed, the characteristics were decreased to 95% or less in comparison with an initial value thereof.

Meanwhile, in Example 1, the peeling did not occur even in the case where 1500 hours elapsed. It was found out that, therefore, the progress of the peeling can be prevented by the first removed portion 23 and the second removed portion 24, even if the moisture that had invaded the first groove portion 17 reached the interface between the glass substrate 11 and the photoelectric conversion layer 13, and the peeling of the photoelectric conversion layer 13 from the glass substrate 11 occurred. Moreover, the width of the photoelectric conversion layer 13, which is of the portion where the peeling occurred, was narrowed. Therefore, a film stress was reduced, and the occurrence of the micro peeling could also be prevented.

Moreover, in Example 2, at a point of time when 1000 hours elapsed, the micro peeling occurred on the non-power generation region 22. Thereafter, at the point of time when 1500 hours elapsed, the progress of the peeling was observed in the non-power generation region 22. However, even in the case where 1500 hours elapsed, the peeling in the power generation region 21 did not occur.

Moreover, in Example 3, in a similar way to Example 1, the peeling did not occur even in the case where 1500 hours elapsed. However, it is naturally supposed that the solar cell module 10 according to Example 3 has higher moisture resistance than the solar cell module 10 according to Example 1.

What is claimed is:

1. A solar cell module in which a plurality of photovoltaic elements is arranged, comprising:
a transparent substrate;
a first electrode stacked on the transparent substrate;
a photoelectric conversion layer stacked on the first electrode;
a second electrode stacked on the photoelectric conversion layer,
a protective member adhered above the second electrode by a sealing material; and
a first removed portion provided in the photoelectric conversion layer, wherein
each of the plurality of photovoltaic elements has a oblong shape that is extended in a longitudinal direction, and is arranged along a direction perpendicular to the longitudinal direction,
a power generation region that includes the plurality of photovoltaic elements is electrically separated from a non-power generation region that is provided along a periphery of the power generation region by a first groove portion,
the first removed portion penetrates the photoelectric conversion layer from the second electrode side to the transparent substrate side,
the first removed portion is provided along the first groove portion in the power generation region, and
the second electrode is filled into the first removed portion.

2. The solar cell module according to claim 1, further comprising:
a second groove portion that separates the photoelectric conversion layer and the second electrode for each of the plurality of photovoltaic elements, wherein
the first removed portion provided along the direction perpendicular to the longitudinal direction is formed on the transparent substrate, and is electrically separated by the second groove portions.

3. The solar cell module according to claim 1, wherein
the first removed portion provided along the longitudinal direction is formed on the transparent substrate or on the first electrode.

4. The solar cell module according to claim 1, further comprising:
a second removed portion provided in the photoelectric conversion layer, wherein
the second removed portion penetrates the photoelectric conversion layer from the second electrode side to the transparent substrate side,
the second removed portion is provided along the first groove portion in the non-power generation region, and
the second electrode is filled into the second removed portion.
